(19) United States
(12) Patent Application Publication
(10) Pub. No.: US 2026/0171980 A1
(43) Pub. Date: Jun. 18, 2026

(54) TRANSMISSION CIRCUIT AND COMMUNICATION APPARATUS EQUIPPED WITH THE SAME

(71) Applicant: Murata Manufacturing Co., Ltd., Nagaokakyo-shi (JP)

(72) Inventor: Kenji TAHARA, Nagaokakyo-shi (JP)

(21) Appl. No.: 19/377,392

(22) Filed: Nov. 3, 2025

(30) Foreign Application Priority Data
Nov. 7, 2024 (JP) 2024-195325

(51) Int. Cl. H03F 1/56; H03F 3/24; H04B 1/04

(52) U.S. Cl. CPC H03F 1/56; H03F 3/245; H04B 1/04; H03F 2200/06; H03F 2200/09; H03F 2200/222; H03F 2200/381; H03F 2200/387; H03F 2200/451; H04B 2001/0408

(57) ABSTRACT

A transmission circuit includes an input terminal, an output terminal, a power amplifier circuit that amplifies a high frequency signal received at the input terminal, a balun, a power supply circuit, and an impedance adjustment circuit. The balun includes an unbalanced line whose first end is connected to the output terminal and balanced lines that are connected to the power amplifier circuit and transmits the high frequency signal amplified by the power amplifier circuit to the output terminal. The power supply circuit selects, based on power of the high frequency signal, one of discrete power supply voltages and supplies the selected power supply voltage to the power amplifier circuit. The impedance adjustment circuit is connected to a second end of the unbalanced line and changes a load impedance in accordance with the power supply voltage supplied to the power amplifier circuit.

### CROSS REFERENCE TO RELATED APPLICATION

This application claims priority from Japanese Patent Application No. 2024-195325, filed on Nov. 7, 2024. The content of these applications are incorporated herein by reference in its entirety.

### BACKGROUND OF THE DISCLOSURE

### 1. Field of the Disclosure

The present disclosure relates to a transmission circuit and a communication apparatus equipped with the same, and more particularly, to a technique for reducing variations in gain of a power amplifier circuit included in the transmission circuit.

### 2. Description of the Related Art

In Japanese Unexamined Patent Application Publication No. 2022-183043, a power amplifier capable of adjusting, by varying in an analog manner a load impedance coupled to an output of the power amplifier in accordance with an envelope signal, which varies correspondingly to the envelope of a radio frequency signal, the impedance at the output, is disclosed.

### BRIEF SUMMARY OF THE DISCLOSURE

For typical power amplifier circuits, improving the efficiency of an amplifier circuit with respect to input signals in a wide modulation band width has been demanded. In recent years, in particular, for high-capacity, high-speed communications, development of communication systems using sub-terahertz frequency bands has progressed. In such systems, loss in a signal path is likely to be large and the impact of a decrease in the efficiency of an amplifier tends to be significant, compared to cases where signals in millimeter wave bands or other frequency bands lower than the millimeter wave bands are used.

In high frequency bands such as sub-terahertz frequency bands, since the variation period of power (output) of a high frequency signal to be outputted is very short, it is very difficult to cause power supply voltage to be supplied to a power amplifier to follow in an analog manner the envelope of the high frequency signal. Therefore, for a power amplifier that amplifies a high frequency signal in such a high frequency band, a digital envelope tracker (digital ET) that supplies power supply voltage by switching between a plurality of power supply voltages is typically used.

However, in the case where a digital ET is used, since switching is performed discretely between power supply voltages, the gain of the power amplifier greatly changes at the time of switching between voltages, and this may cause noise.

As a method for reducing variations in gain at the time of switching between power supply voltages, switching may be performed between subdivided power supply voltage values. However, in order to subdivide power supply voltage into finer levels, the number of DC/DC converters for setting voltage levels needs to be increased. The increase in the number of DC/DC converters requires a large circuit area. Therefore, the size of an apparatus may increase, and this may hinder miniaturization.

Instead of the method mentioned above, a method for increasing the number of voltage levels by changing the combination of outputs of DC/DC converters without increasing the number of DC/DC converters, may be considered. In this case, however, because a switching circuit for changing the combination is needed, loss in the switching circuit increases. Thus, the efficiency of the power amplifier circuit may rather degrade.

The present disclosure has been designed to solve the problems mentioned above, and it is a possible benefit of the present disclosure to reduce variations in gain of a power amplifier circuit included in a transmission circuit.

A transmission circuit according to the present disclosure includes an input terminal, an output terminal, an amplifier circuit that amplifies a high frequency signal received at the input terminal, a first balun, a power supply circuit, and an impedance adjustment circuit. The first balun includes an unbalanced line whose first end is connected to the output terminal and a first balanced line and a second balanced line that are connected to the amplifier circuit, the first balun transmitting the high frequency signal amplified by the amplifier circuit to the output terminal. The power supply circuit selects, based on power of the high frequency signal, one of discrete power supply voltages and supplies the selected power supply voltage to the amplifier circuit. The impedance adjustment circuit is connected to a second end of the unbalanced line of the first balun and changes a load impedance in accordance with the power supply voltage supplied to the amplifier circuit.

The transmission circuit according to the present disclosure is a transmission circuit using a so-called digital ET, and the impedance adjustment circuit is provided for the unbalanced line of the balun connected to the output terminal. Since efficiency of the amplifier circuit can be adjusted by changing the load impedance, a decrease in the gain of the amplifier circuit can be suppressed by selecting a load impedance that is suitable for a supplied power supply voltage. Thus, variations in the gain of the power amplifier circuit included in the transmission circuit can be reduced.

### BRIEF DESCRIPTION OF THE SEVERAL VIEWS OF THE DRAWINGS

FIG. 1 is a schematic configuration diagram of a communication apparatus to which a transmission circuit according to an embodiment is applied;

FIG. 2 is a diagram illustrating a detailed configuration of an impedance adjustment circuit in FIG. 1;

FIG. 3 is a diagram illustrating a detailed structure of a balun;

FIG. 4 is a diagram for explaining output gain that varies depending on the envelope tracking mode;

FIG. 5 includes diagrams for explaining changes in an impedance between balanced lines in the case where the frequency of an input high frequency signal changes at a load impedance of 50 Ω;

FIG. 6 is a diagram for explaining changes in band pass characteristics (insertion loss) in the case of FIG. 5;

FIG. 7 is an enlarged diagram of a part of the diagram in FIG. 6;

FIG. 8 includes diagrams for explaining changes in an impedance between outputs of a power amplifier circuit in the case where the load impedance changes;

FIG. 9 is a diagram for explaining changes in gain for the case where the load impedance is changed;

FIG. 10 is a diagram for explaining changes in gain in a first modification in which the power supply voltage level is changed;

FIG. 11 is a diagram illustrating arrangement of devices in a communication apparatus according to an embodiment; and

FIG. 12 is a diagram illustrating arrangement of devices in a communication apparatus according to a second modification.

### DETAILED DESCRIPTION OF THE DISCLOSURE

Hereinafter, embodiments of the present disclosure will be described in detail with reference to the drawings. In the drawings, the same signs are assigned to the same or corresponding parts, and repetitive description of those same or corresponding parts will be omitted.

### Configuration of Communication Apparatus

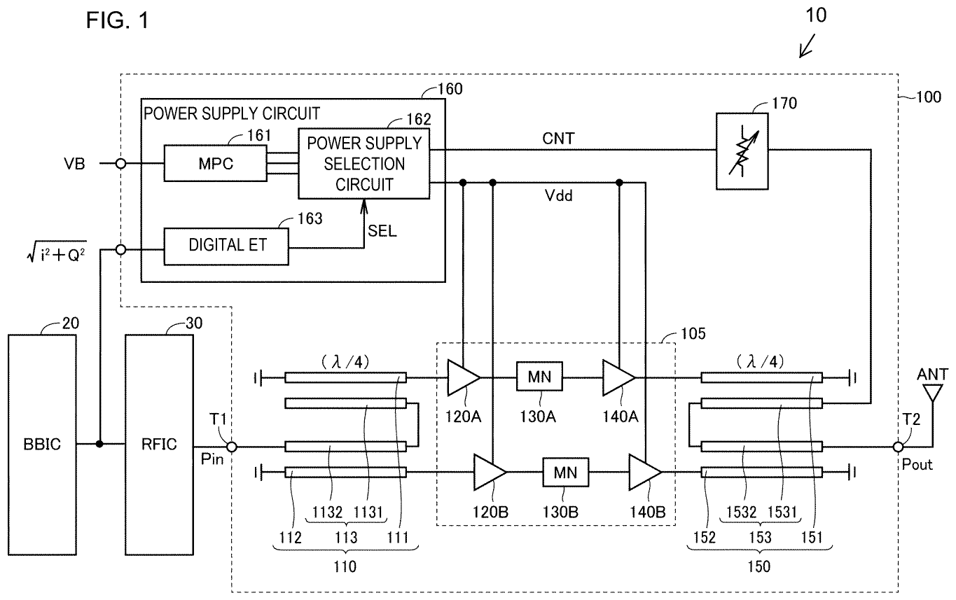

FIG. 1 is a schematic configuration diagram of a communication apparatus 10 to which a transmission circuit 100 according to a first embodiment is applied. The communication apparatus 10 is, for example, a mobile terminal such as a mobile phone, a smartphone, or a tablet, a personal computer having a communication function, or the like.

Referring to FIG. 1, the communication apparatus 10 includes an antenna ANT, the transmission circuit 100, a baseband integrated circuit (BBIC) 20 including a baseband signal processing circuit, and a radio frequency integrated circuit (RFIC) 30. The transmission circuit 100 includes an input terminal T1, an output terminal T2, a power amplifier circuit 105, baluns 110 and 150, a power supply circuit 160, and an impedance adjustment circuit 170. Schematically speaking, in the communication apparatus 10, the RFIC 30 up-converts an intermediate frequency (IF) signal transmitted from the BBIC 20 into a high frequency (radio frequency (RF)) signal, the power amplifier circuit 105 amplifies the high frequency signal, and the amplified high frequency signal is radiated from the antenna ANT.

The RFIC 30 is an example of a signal processing circuit that processes a high frequency signal. The RFIC 30 up-converts an intermediate frequency signal transmitted from the BBIC 20 into a high frequency signal, and outputs the generated high frequency signal through the input terminal T1 to the transmission circuit 100.

The power supply circuit 160 is an example of a so-called digital envelope tracker and is capable of supplying power supply voltages Vdd at different voltage levels to the power amplifier circuit 105. The power supply circuit 160 includes a multilevel power converter (MPC) 161, a power supply selection circuit 162, and a digital ET 163.

Although not illustrated in FIG. 1, the MPC 161 includes a plurality of DC/DC converters. The MPC 161 converts a battery voltage VB supplied from an external battery into different voltage levels and supplies the different voltage levels to the power supply selection circuit 162.

The digital ET 163 receives I/Q waveform signals of a transmission signal from the BBIC 20 and tracks the envelope of the transmission signal based on a digital ET mode. The digital ET 163 generates a selection signal SEL corresponding to the voltage level of the envelope of the transmission signal, and outputs the generated selection signal SEL to the power supply selection circuit 162.

The power supply selection circuit 162 selects a voltage corresponding to the selection signal SEL from among the plurality of voltage levels supplied from the MPC 161 to generate a power supply voltage Vdd to be supplied to the power amplifier circuit 105. The generated power supply voltage Vdd is supplied to the power amplifier circuit 105. The power supply selection circuit 162 also functions as a circuit for controlling the impedance adjustment circuit 170. The power supply selection circuit 162 generates a control signal CNT corresponding to the selected voltage level, and outputs the generated control signal CNT to the impedance adjustment circuit 170.

Each of the baluns 110 and 150 is a conversion element for conversion between a pair of balanced lines and an unbalanced line. In this embodiment, since high frequency signals in a sub-terahertz frequency band are used, Marchand baluns are used as the baluns 110 and 150.

Apart from baluns, magnet coupling transformers (MCTs) may be used for conversion between a balanced line and an unbalanced line. However, in the case of a sub-terahertz frequency band, miniaturization causes an increase of magnetic coupling. This rather causes an increase of loss, and a band width may be decreased. Thus, in the case where high frequency signals in a sub-terahertz frequency band are used, an increase of the loss can be suppressed by using baluns rather than MCTs.

The balun 110 is a balun on an input side and converts an input signal Pin inputted to an unbalanced line into a pair of balanced lines. The power amplifier circuit 105 amplifies a high frequency signal converted by the balun 110, and outputs the amplified high frequency signal to the balun 150 on an output side. By converting a pair of balanced lines into an unbalanced line, the balun 150 combines high frequency signals transmitted from the power amplifier circuit 105 to generate an output signal Pout. The generated output signal Pout passes through the output terminal T2 and is radiated from the antenna ANT.

More particularly, the balun 110 includes lines 111 and 112 corresponding to the pair of balanced lines and a line 113 corresponding to the unbalanced line. The lines 111 and 112 each have a line length of ¼ wavelength (λ/4) and the line 113 has a line length of ½ wavelength (λ/2), where the wavelength of a center frequency of a high frequency signal to be transmitted by the transmission circuit 100 is represented by λ.

One end of the line 113 is connected to the input terminal T1, and the other end is an open end. The line 113 has a configuration in which a first part 1131 coupled to the line 111 and a second part 1132 coupled to the line 112 are connected in series. The first part 1131 and the second part 1132 each have a line length of λ/4.

One end of the first part 1131 is open, and the other end of the first part 1131 is connected to one end of the second part 1132. The other end of the second part 1132 is connected to the input terminal T1. Coupling between the first part 1131 and the line 111 and coupling between the second part 1132 and the line 112 have phases opposite to each other. That is, the input signal Pin inputted to the input terminal T1 is transmitted to the line 111 and the line 112 as signals of phases opposite to each other.

One end of the line 111 is connected to an amplifier 120A in the power amplifier circuit 105, and the other end of the line 111 is connected to a ground potential. Similarly, one end of the line 112 is connected to an amplifier 120B in the power amplifier circuit 105, and the other end of the line 112 is connected to the ground potential.

The power amplifier circuit 105 includes amplifiers 140A and 140B and matching circuits (matching networks (MNs)) 130A and 130B, in addition to the amplifiers 120A and 120B. The amplifiers 140A and 140B are main amplifiers in the power amplifier circuit 105, and the amplifiers 120A and 120B are driving amplifiers for driving the amplifiers 140A and 140B, respectively.

The amplifier 120A is connected to the amplifier 140A with the matching circuit 130A interposed therebetween. Similarly, the amplifier 120B is connected to the amplifier 140B with the matching circuit 130B interposed therebetween. High frequency signals amplified by the amplifiers 120A and 120B are further amplified by the amplifiers 140A and 140B and then transmitted to the balun 150.

In the power amplifier circuit 105 in this embodiment, two-stage amplifiers are provided for each line. However, the circuit configuration of amplifiers for individual lines is not limited to the configuration described above. For example, a single amplifier may be arranged for each line or a Doherty circuit including a carrier amplifier and a peak amplifier may be arranged for each line.

The matching circuits 130A and 130B are impedance matching circuits. Although not illustrated in the drawings, the matching circuits 130A and 130B each include an inductor and/or a capacitor. In the case where there is no need to adjust impedance, the matching circuits 130A and 130B are not necessarily provided.

The balun 150 includes lines 151 and 152 corresponding to the pair of balanced lines and a line 153 corresponding to the unbalanced line. The lines 151 and 152 each have a line length of ¼ wavelength (λ/4), and the line 153 has a line length of ½ wavelength (λ/2).

One end of the line 151 is connected to an output end of the amplifier 140A, and the other end of the line 151 is connected to the ground potential. Similarly, one end of the line 152 is connected to an output end of the amplifier 140B, and the other end of the line 152 is connected to the ground potential.

The line 153 has a configuration in which a first part 1531 coupled to the line 151 and a second part 1532 coupled to the line 152 are connected in series. The first part 1531 and the second part 1532 each have a line length of λ/4.

Coupling between the first part 1531 and the line 151 and coupling between the second part 1532 and the line 152 have phases opposite to each other. Since conversion into high frequency signals of phases opposite to each other is performed in the balun 110 on the input side, high frequency signals transmitted to the line 151 and the line 152 are combined into the same phase in the line 153.

One end of the line 153 is connected to the output terminal T2. The high frequency signal combined in the line 153 passes through the output terminal T2 as the output signal Pout and is radiated from the antenna ANT.

In contrast, the other end of the line 153 is connected to the impedance adjustment circuit 170. The impedance adjustment circuit 170 is a circuit for adjusting a load impedance. The impedance adjustment circuit 170 is controlled in accordance with the control signal CNT from the power supply selection circuit 162, and the load impedance is changed in accordance with the power supply voltage Vdd supplied to the power amplifier circuit 105.

### Configuration of Impedance Adjustment Circuit

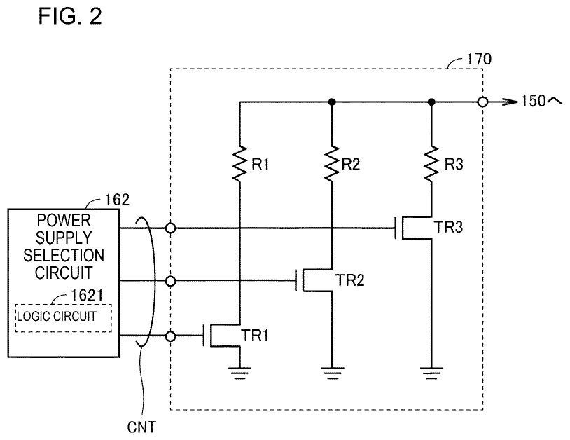

FIG. 2 is a diagram illustrating a detailed configuration of the impedance adjustment circuit 170 of FIG. 1. In an example of this embodiment, the impedance adjustment circuit 170 is a variable resistance circuit capable of adjusting a load resistance and includes resistors R1 to R3 and switches TR1 to TR3.

The resistors R1 to R3 are connected in parallel between the other end of the line 153 in the balun 150 and the ground potential in FIG. 1. The switch TR1 is connected in series to the resistor R1, the switch TR2 is connected in series to the resistor R2, and the switch TR3 is connected in series to the resistor R3.

Each of the switches TR1 to TR3 is, for example, a semiconductor switch. Each of the switches TR1 to TR3 is controlled in accordance with the control signal CNT generated by a logic circuit 1621 included in the power supply selection circuit 162, and switching between electrical connection and electrical disconnection is performed. The load resistance may be switched by selecting any one of the resistors R1 to R3. Switching of the load resistance may be performed by, instead of that or in addition to that, changing the combination of the resistors R1 to R3.

The logic circuit 1621 changes the control signal CNT in accordance with the selection signal SEL generated by the digital ET 163. More specifically, as described later, when the power supply voltage Vdd decreases, the logic circuit 1621 generates a control signal CNT that increases a resistance value (that is, impedance). On the other hand, when the power supply voltage Vdd increases, the logic circuit 1621 generates a control signal CNT that decreases a resistance value.

Referring to FIG. 2, the example in which the impedance adjustment circuit 170 is a variable resistance circuit has been described. However, the impedance adjustment circuit 170 may be configured in a different manner as long as impedance can be changed. For example, the impedance adjustment circuit 170 may be a variable capacitor capable of changing a capacitance value.

### Detailed Structure of Balun

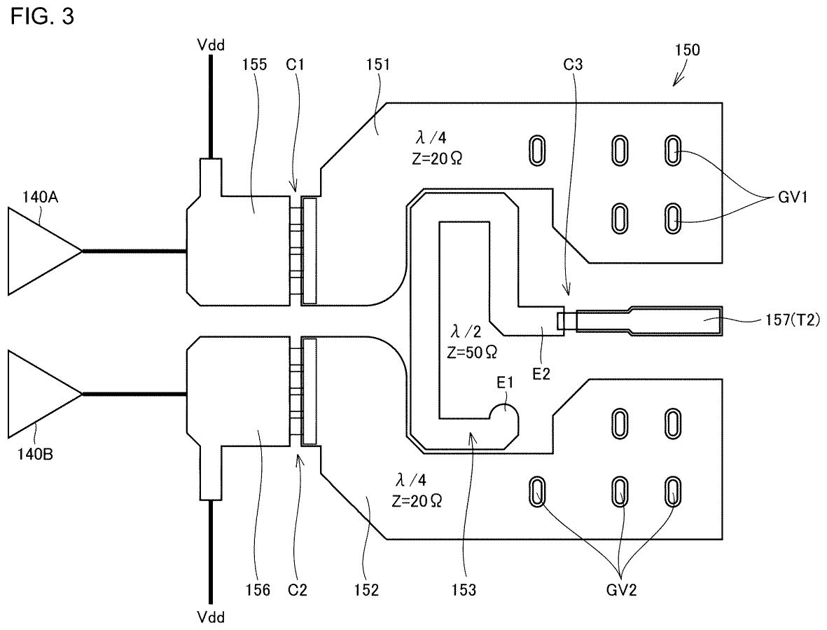

FIG. 3 is a diagram illustrating a detailed structure of a balun. In FIG. 3, the balun 150 on the output side will be explained as an example.

The balun 150 is formed on a dielectric substrate or a semiconductor substrate. The balun 150 further includes terminals 155 to 157, in addition to the lines 151 to 153. The output of the amplifier 140A is connected to the terminal 155. The output end of the amplifier 140B is connected to the terminal 156. The power supply voltage Vdd is supplied to the terminal 155 and the terminal 156.

The terminal 157 technically corresponds to the output terminal T2 in FIG. 1. Although not illustrated in FIG. 3, the antenna ANT is connected to the terminal 157.

The lines 151 and 152, which are balanced lines, are belt-shaped flat-plate electrodes each with a substantially letter C shape and are arranged symmetrically in such a manner that recessed parts of the letter C shapes face each other. One end of the line 151 is arranged to face the terminal 155. Capacitive coupling occurs between the line 151 and the terminal 155, and a capacitor C1 is thus formed between the line 151 and the terminal 155.

A plurality of vias GV1 are connected to the other end of the line 151. Although not illustrated in FIG. 3, the vias GV1 are connected to the ground potential.

Similarly, one end of the line 152 is arranged to face the terminal 156. Capacitive coupling occurs between the line 152 and the terminal 156, and a capacitor C2 is thus formed between the line 152 and the terminal 156. A plurality of vias GV2 are connected to the other end of the line 152.

The unbalanced line 153 is a belt-shaped flat-plate electrode and is arranged to wind around a normal direction of the substrate in a space between the line 151 and the line 152. One end portion E1 of the line 153 is arranged to face the terminal 157. Capacitive coupling occurs between the end portion E1 and the terminal 157, and a capacitor C3 is thus formed between the end portion E1 and the terminal 157. Although not illustrated in FIG. 3, the other end portion E2 of the line 153 is connected to the impedance adjustment circuit 170, as described above with reference to FIG. 2.

In the balun 150 in the example of FIG. 3, the line width of each of the lines 151 and 152 is wider than the line width of the line 153. With this arrangement, impedance conversion can be achieved in the balun 150.

Specifically, since the line 153 is connected to the antenna ANT, the impedance of the line 153 is set to 50 Ω, which is a characteristic impedance. In contrast, the impedance of each of the lines 151 and 152 is set to 20 Ω. Since the power amplifier circuit 105, which amplifies a high frequency signal, is connected to the lines 151 and 152, a low impedance is set so that transmission loss can be reduced.

### Load Impedance Change Process

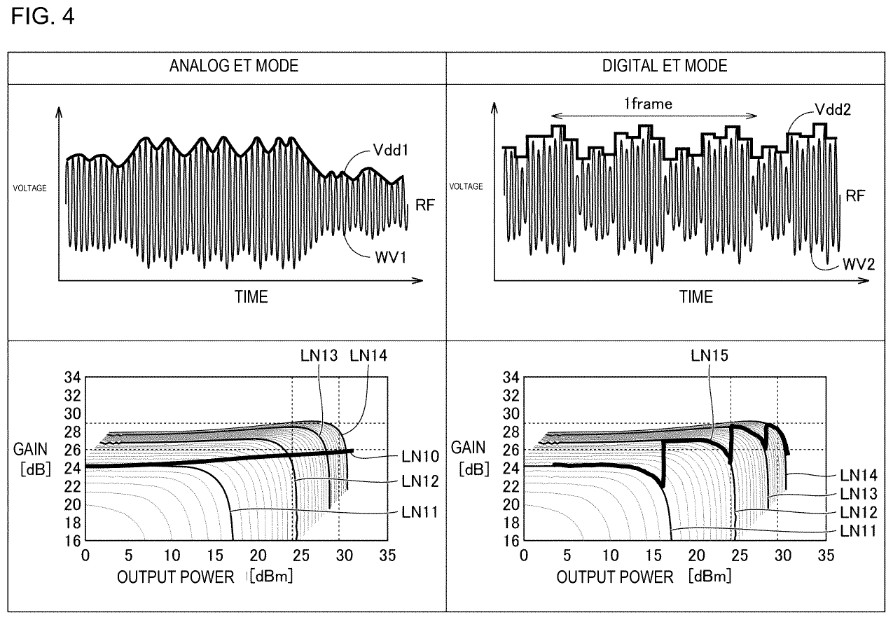

Next, a possible benefit for the case where a digital ET is used, and a load impedance change process in an embodiment will be described with reference to FIG. 4. FIG. 4 is a diagram for explaining output gain that varies depending on the envelope tracking mode of a transmission signal. In FIG. 4, a case where an analog ET mode is used as a tracking mode is illustrated in a column on the left side, and a case where a digital ET is used is illustrated in a column on the right side. Furthermore, in each of the modes, transition of the power supply voltage with time is illustrated on the upper side, and gain changes are illustrated on the lower side.

In graphs indicating power supply voltages on the upper side, the horizontal axis represents time, and the vertical axis represents voltage. Thick solid lines Vdd1 and Vdd2 represent power supply voltages in the individual modes, and thin solid lines WV1 and WV2 represent output signals Pout, which are modulated high frequency signals.

In graphs indicating gain changes on the lower side, the horizontal axis represents gain, and the vertical axis represents output power. Thin solid lines including lines LN11 to LN14 in FIG. 4 represent gain curves for individual power supply voltages Vdd. Furthermore, thick solid lines LN10 and LN15 indicate transition of gains in the individual tracking modes.

In the analog ET mode, a power supply voltage that continuously changes following the envelope of an input signal is set. The waveform of the power supply voltage in the analog ET mode is not a digital waveform, but is an analog waveform.

In the case of the analog ET mode, the power supply voltage Vdd1 that corresponds to variations in the amplitude of an input signal is always supplied. Thus, it is considered that the most efficient tracking can be achieved. In this case, as indicated by the line LN10, the gain changes gradually with respect to changes of the output power.

In contrast, in the digital ET mode, power supply voltages of discrete voltage levels are set within one frame. The power supply voltage has a digital waveform, and a rectangular wave is formed. Specifically, in the digital ET mode, a voltage level that corresponds to the voltage of an input signal in a target section within a frame is selected, based on an envelope signal, from among the plurality of different voltage levels. At this time, the voltage level is selected so that the envelope of a carrier wave modulated based on transmission information is tracked. More specifically, with reference to the range of envelope values associated with the different voltage levels, a voltage level that corresponds to an envelope value of each symbol is selected.

In the example of FIG. 4, voltages represented as the lines LN11, LN12, LN13, and LN14 are set as voltage levels. In this case, when an input signal changes and switching to a voltage level is performed, gain changes along a gain curve corresponding to the voltage level. Therefore, as indicated by the line LN15, the gain may change in a non-continuous manner at a point of switching between voltage levels.

From the point of view of reducing variations in the gain, the analog ET mode may be used. However, since the power supply voltage needs to be changed continuously in the analog ET mode, in the case of a high frequency band such as a sub-terahertz frequency band, the power supply voltage may be unable to follow the envelope of a modulated high frequency signal. Therefore, the digital ET mode needs to be used for a high frequency band such as a sub-terahertz frequency band. As described above, however, the gain changes greatly in a non-continuous manner at the time of switching between voltage levels, and this may cause noise.

It is known that in typical amplifiers, when a load impedance changes with respect to the same input signal, gain of an output signal varies. More specifically, the gain increases as the load impedance increases.

For example, with respect to a specific power P, Equation (1) is satisfied, where output power when the load impedance is set to R is represented by Vₒᵤₜ₁.

P=(V_{OUT1})²/R (1)

With respect to the same power P, Equation (2) is satisfied, where output power when the load impedance is set to 2R is represented by Vₒᵤₜ₂.

P=(V_{OUT2})²/2R (2)

Based on Equation (1) and Equation (2), Equation (3) is satisfied.

P=(V_{OUT1})²/R=(V_{OUT2})²/2R (3)

Equation (3) can be transformed into (V_{OUT2})²=(√2)²×(V_{OUT1})². Thus, voltage becomes √2 times, and as a result, the gain improves by 3 dB.

Thus, in the transmission circuit 100 according to this embodiment, a configuration is adopted in which the load impedance is changed by the impedance adjustment circuit 170 in accordance with a change of the power supply voltage Vdd. More specifically, the impedance adjustment circuit 170 is controlled to increase the load impedance as the power supply voltage Vdd decreases. Accordingly, since the gain in an area where the voltage of an input signal is relatively low can be increased, variations in the gain at the time of switching between power supply voltages can be reduced.

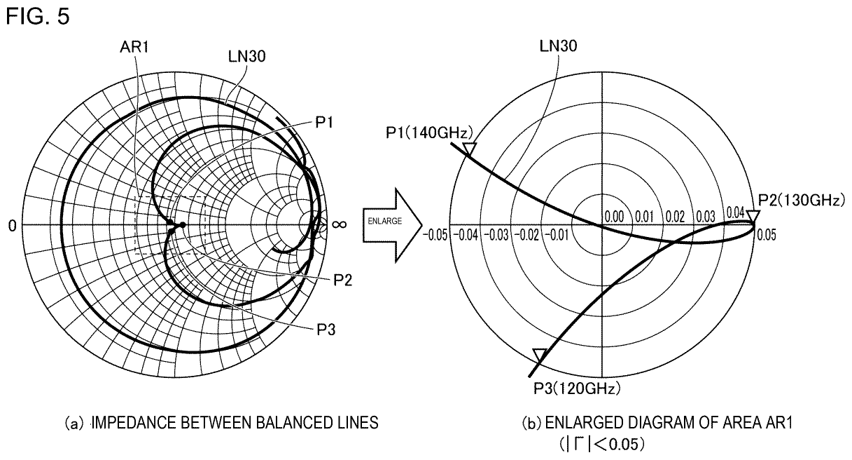

Next, results of simulation about a load impedance change process in an embodiment will be described with reference to FIGS. 5 to 9.

FIG. 5 includes diagrams (line LN30) for explaining changes in impedance between balanced lines for the case where the frequency of an input high frequency signal is changed from 40 GHz to 300 GHz when the load impedance is 50 Ω, which is a characteristic impedance. A right diagram (b) is an enlarged diagram of the vicinity of an area AR1 in a Smith chart of a left diagram (a). A part in which the absolute value of a reflection coefficient Γ is less than 0.05 is enlarged in the right diagram (b).

In the example of FIG. 5, a frequency band to be transmitted is within the range from 120 GHz to 140 GHz, and each parameter is set so that |Γ|<0.05 is satisfied in this range. P1 represents impedance at 140 GHz, P2 represents impedance at 130 GHz, and P3 represents impedance at 120 GHz.

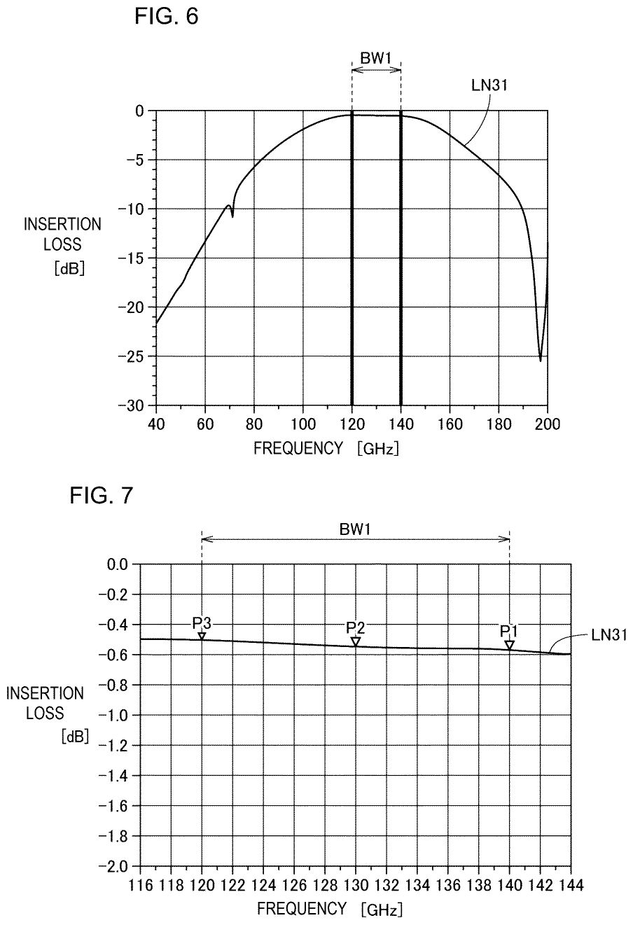

FIGS. 6 and 7 are diagrams (line LN31) illustrating bandpass characteristics (insertion loss) in the state of FIG. 5. FIG. 7 is an enlarged diagram of the vicinity of a frequency band BW1 (120 GHz to 140 GHz) of FIG. 6. As illustrated in FIGS. 6 and 7, the insertion loss ranges from 0.5 dB to 0.6 dB over the entire range of the frequency band BW1.

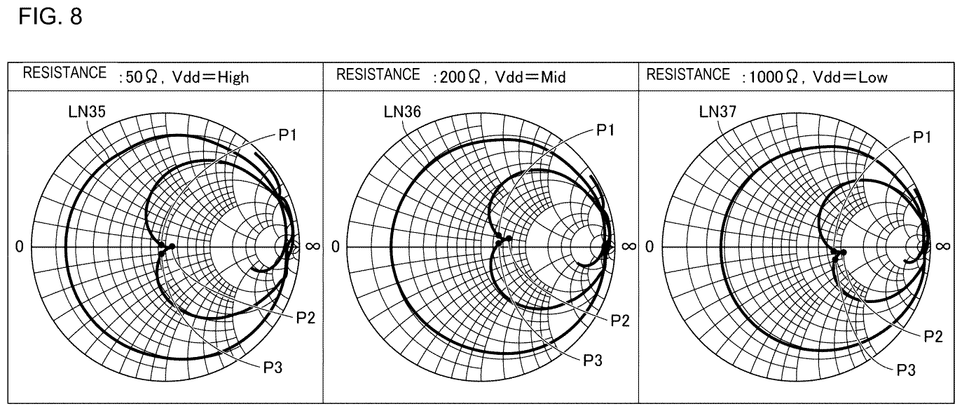

Changes in impedance between outputs of the power amplifier circuit 105 (that is, impedance between the balanced lines of the balun 150) when the power supply voltage Vdd is decreased and the load impedance is increased in accordance with the decrease of the power supply voltage Vdd in the case where the state mentioned above is set as a reference state with the maximum power supply voltage Vdd, are illustrated in FIG. 8. In a column on the left side in FIG. 8, a Smith chart (line LN35) for the case where the load impedance is 50 Ω, which is a reference impedance, is illustrated. The power supply voltage Vdd at this time is defined as High.

In a column at the center, a Smith chart (line LN36) for the case where the power supply voltage Vdd is slightly decreased (Vdd=Mid) is illustrated, and the load impedance at this time is set to 200 Ω. In a column on the right side, a Smith chart (line LN37) for the case where the power supply voltage Vdd is further decreased (Vdd=Low) is illustrated, and the load impedance at this time is set to 1,000 Ω.

As illustrated in FIG. 8, by increasing the load impedance in accordance with a decrease of the power supply voltage Vdd, the impedance between the balanced lines at the center frequency (130 GHz) increases approximately 1.5 times. Thus, although power of the amplifiers 140A and 140B in the power amplifier circuit 105 slightly decreases, efficiency improves.

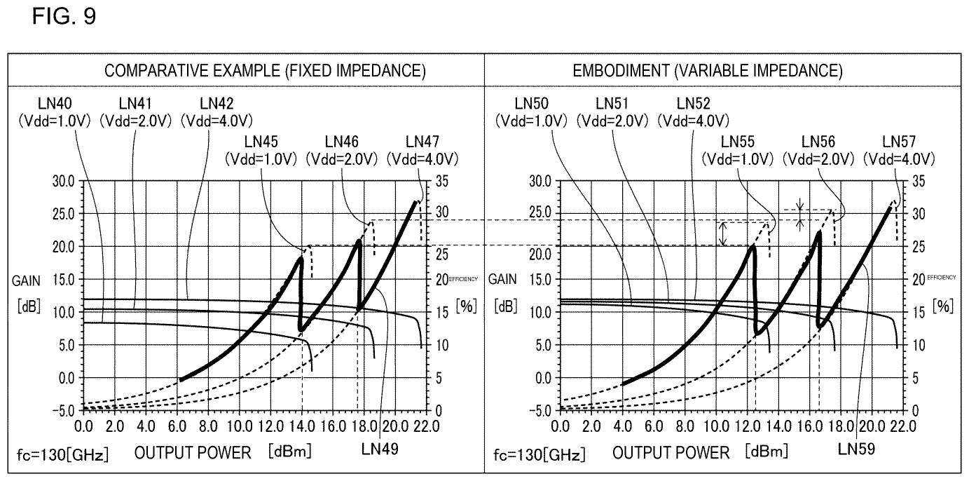

FIG. 9 is a diagram for explaining changes in gain for the case where the load impedance is changed as illustrated in FIG. 8. In the column on the left side in FIG. 8, a graph of a comparative example in which the load impedance is fixed with respect to changes of the power supply voltage Vdd is illustrated. In the column on the right side in FIG. 8, a graph of an embodiment in which the load impedance is changed with respect to changes of the power supply voltage Vdd is illustrated.

In each graph, the horizontal axis represents output power, and the vertical axis represents gain (left axis) and efficiency (right axis). In the graphs of FIG. 9, solid lines LN40 to LN42 and LN50 to LN52 represent gain. In the graphs of FIG. 9, broken lines LN45 to LN47 and LN55 to LN57 represent efficiency.

In each graph, the frequency of a transmission signal is 130 GHz. The lines LN40, LN45, LN50, and LN55 represent cases where the power supply voltage Vdd is 1.0 V. The lines LN41, LN46, LN51, and LN56 represent cases where the power supply voltage Vdd is 2.0 V. The lines LN42, LN47, LN52, and LN57 represent cases where the power supply voltage Vdd is 4.0 V.

Referring to FIG. 9, when attention is paid to gain, the gains (lines LN50 and LN51) for the case where the power supply voltage Vdd is 1.0 V and 2.0 V in the embodiment are higher than the gains (lines LN40 and LN41) in the comparative example.

Furthermore, when attention is paid to efficiency, by increasing the load impedance, the peak efficiencies (lines LN55 and LN56) for the case where the power supply voltage Vdd is 1.0 V and 2.0 V in the embodiment are improved compared to the peak efficiencies (lines LN45 and LN46) in the comparative example.

However, since saturation power decreases as the load impedance increases (lines LN50, LN51, and LN52), the point at which switching between the power supply voltage levels is performed changes from 14.0 dBm to 12.4 dBm when the power supply voltage Vdd is 1.0 V and changes from 17.6 dBm to 16.6 dBm when the power supply voltage Vdd is 2.0 V (lines LN49 and LN59).

As described above, the efficiency of the power amplifier circuit 105 at a low voltage level can be improved by increasing the load impedance in accordance with a decrease of the power supply voltage Vdd. As a result, the gain can be increased. Thus, since variations in the gain caused by changes in the power supply voltage Vdd are reduced, noise caused by changes in the power supply voltage Vdd can be reduced.

The “balun 150” and the “balun 110” in an embodiment are examples of a “first balun” and a “second balun” in the present disclosure. The “amplifier 120A” and the “amplifier 140A” in an embodiment are examples of a “first amplifier” in the present disclosure. The “amplifier 120B” and the “amplifier 140B” in an embodiment are examples of a “second amplifier” in the present disclosure.

### First Modification

In the example of FIG. 9, the voltage levels of the power supply voltage Vdd are under the same conditions between the comparative example and the embodiment. In this case, as described above, the peak efficiency is improved in accordance with an increase of the load impedance. However, a point at which the power supply voltage Vdd is switched becomes lower in accordance with a decrease of the saturation power.

That is, by making the load impedance variable, the output power of an amplifier can be increased. Thus, by switching to a higher voltage level of the power supply voltage Vdd to increase saturation power of the amplifier, a further improvement in the efficiency can be achieved.

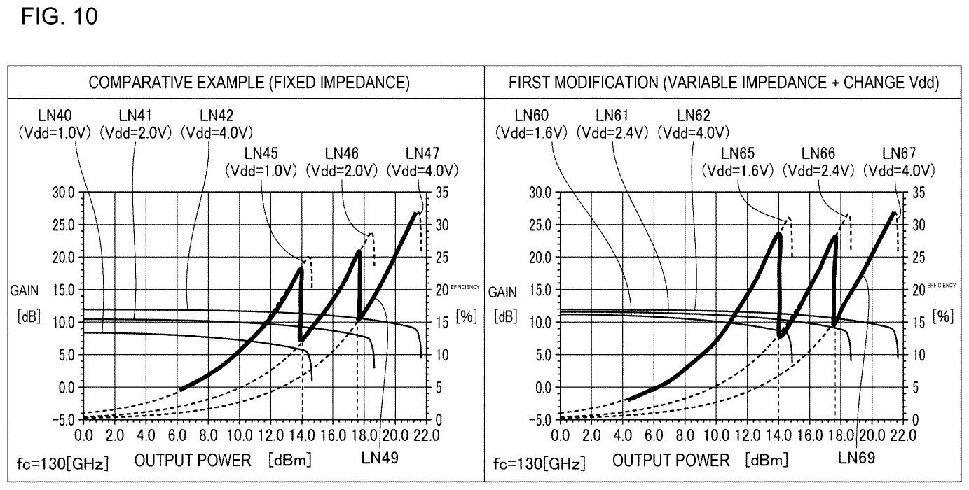

FIG. 10 is a diagram for explaining changes in gain in the first modification in which the voltage level of the power supply voltage Vdd is changed, in addition to that the load impedance is increased in accordance with a decrease of the power supply voltage level, as in FIG. 9. More particularly, in the first modification, while the maximum voltage level of the power supply voltage Vdd is maintained at 4.0 V, relatively low voltage levels of the power supply voltage Vdd are set to 1.6 V and 2.4 V.

In a column on the left side in FIG. 10, a graph of the comparative example of FIG. 9 is illustrated. In a column on the right side in FIG. 10, a graph of the first modification is illustrated. In the graph on the right side, lines LN60 to LN62 represent gain and broken lines LN65 to LN67 represent efficiency. Furthermore, the lines LN60 and LN65 represent cases where the power supply voltage Vdd is 1.6 V, the lines LN61 and LN66 represent cases where the power supply voltage Vdd is 2.4 V, and the lines LN62 and LN67 represent cases where the power supply voltage Vdd is 4.0 V.

By setting the power supply voltage Vdd to 1.6 V and 2.4 V, the saturation power increases, and the point at which the power supply voltage Vdd is switched is set to 14.0 dBm and 17.6 dBm, as in the comparative example. The peak efficiency at each power supply voltage Vdd is further improved (line LN69), and the gain also increases (lines LN60 and LN61). Thus, variations in the gain caused by switching of the power supply voltage Vdd are further reduced.

As described above, through a design that allows the load impedance to increase in accordance with a decrease of the power supply voltage Vdd and allows switching to a higher voltage level of the power supply voltage Vdd, the power amplifier circuit 105 can be caused to operate with a higher efficiency. Thus, compared to the embodiment illustrated in FIG. 9, noise caused by changes in the power supply voltage Vdd can further be reduced.

### Arrangement of Devices in Communication Apparatus

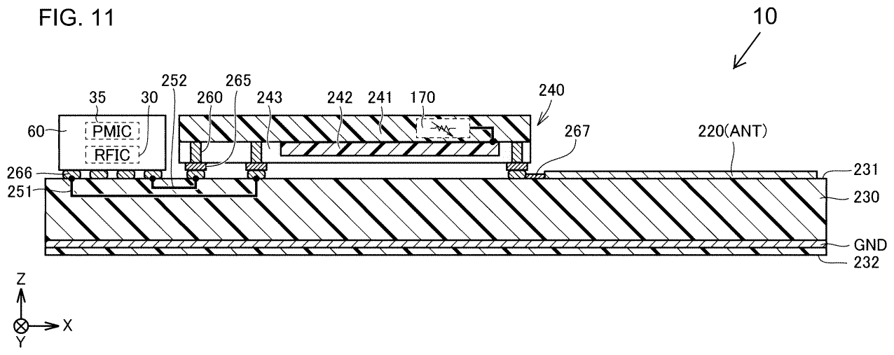

Arrangement of devices in the communication apparatus 10 according to an embodiment will be described with reference to FIG. 11. FIG. 11 is a perspective side view of the communication apparatus 10 described above with reference to FIG. 1.

Referring to FIG. 11, the communication apparatus 10 includes a radiating element 220, a dielectric substrate 230, a system in package (SiP) module 60, and an amplifier module 240 in which the power amplifier circuit 105 is formed. In the perspective side view of FIG. 10 and a perspective side view of FIG. 11, which will be described later, a normal direction of a main surface of the dielectric substrate 230 is defined as a Z-axis, and a face perpendicular to the Z-axis is defined as an X-Y plane. In FIG. 10, the horizontal direction in the drawing is defined as an X-axis direction, and the depth direction is defined as a Y-axis direction.

The dielectric substrate 230 has a main surface 231 (first surface) and a main surface 232 (second surface) that are opposite to each other. The dielectric substrate 230 is a low temperature co-fired ceramics (LTCC) multilayer substrate, a multilayer resin substrate formed by laminating a plurality of resin layers made of resin such as epoxy or polyimide, a multilayer resin substrate formed by laminating a plurality of resin layers made of liquid crystal polymer (LCP) having a lower permittivity, a multilayer resin substrate formed by laminating a plurality of resin layers made of fluorine-based resin, or a ceramics multilayer substrate made of materials other than LTCC. The dielectric substrate 230 does not necessarily have a multilayer structure and may be a single-layer substrate.

The radiating element 220 corresponds to the antenna ANT in FIG. 1. The radiating element 220 is disposed on the main surface 231 (a surface in the Z-axis positive direction) of the dielectric substrate 230. In the example of FIG. 11, the radiating element 220 is a patch antenna of a flat-plate shape. In FIG. 11, the example in which the radiating element 220 is exposed out of the main surface 231 is illustrated. However, the radiating element 220 may be disposed at an inner layer of the dielectric substrate 230.

In the dielectric substrate 230, a ground electrode GND is arranged, opposing the radiating element 220, over the entire dielectric layer between the radiating element 220 and the main surface 232.

The amplifier module 240 includes a semiconductor substrate 241 and a semiconductor substrate 242. The semiconductor substrate 242 is arranged on a main surface of the semiconductor substrate 241 in the Z-axis negative direction and is electrically connected to the semiconductor substrate 241. The semiconductor substrate 242 is molded by an insulative resin 243 on the semiconductor substrate 241.

The amplifier module 240 is mounted on the main surface 231 of the dielectric substrate 230. The semiconductor substrate 241 is electrically connected to the dielectric substrate 230 with a columnar electrode 260 and a connecting electrode 265 that are disposed at the resin 243 for molding and a solder bump 266 interposed therebetween.

The semiconductor substrate 241 is, for example, a semiconductor substrate made of a Si-based base material, such as silicon-germanium (SiGe). In contrast, the semiconductor substrate 242 is a semiconductor substrate made of a material containing, as a main component, a compound of an element from group III and an element from group V (hereinafter, may also be referred to as a “group III-V compound”) such as gallium nitride (GaN), gallium arsenide (GaAs) or indium phosphide (InP), as a base material.

In the semiconductor substrate 242, the amplifiers 120A, 120B, 140A, and 140B in the power amplifier circuit 105 in FIG. 1 are formed. In contrast, in the semiconductor substrate 241, the matching circuits 130A and 130B, the baluns 110 and 150, and the impedance adjustment circuit 170 in the power amplifier circuit 105 are formed.

The SiP module 60 includes a power management integrated circuit (PMIC) 35 that performs power supply control, in addition to the RFIC 30. The PMIC 35 is a circuit for supplying driving power to operate the power amplifier circuit 105 and corresponds to the power supply circuit 160 in FIG. 1.

A high frequency signal and the power supply voltage Vdd from the SiP module 60 are transmitted, through power supply wires 251 and 252 arranged inside the dielectric substrate 230, to the amplifier module 240. Furthermore, the output signal Pout amplified in the transmission circuit 100 is transmitted, through a power supply wire 267 arranged at the main surface 231 of the dielectric substrate 230, to the radiating element 220.

For semiconductor substrates for forming a semiconductor device used for an amplifier, Si-based materials, which are relatively low in cost and suitable for mass production, are typically used. However, since loss in Si-based materials tend to be high in a sub-terahertz frequency band of 100 GHz or more, it may be difficult to achieve characteristics required for semiconductor devices.

In contrast, materials for group III-V compounds such as GaN, GaAs, or InP are high in unit price compared to Si-based materials, whereas they have power density higher than that of Si-based materials. Therefore, materials for the group III-V compounds have the characteristics of having low loss also in a sub-terahertz frequency band, compared to substrates made of Si-based materials.

Thus, by forming the amplifiers 120A, 120B, 140A, and 140B in which a relatively large current flows in the amplifier module 240 at the semiconductor substrate 242 made of a material for a low-loss group III-V compound and forming other circuits at the semiconductor substrate 241 made of an Si-based material or inside the SiP module 60, an increase of the cost can be suppressed, and at the same time, circuit efficiency can be improved.

With reference to FIG. 11, the example in which the impedance adjustment circuit 170 is formed at the semiconductor substrate 241 has been described. However, the impedance adjustment circuit 170 may be arranged in the SiP module 60.

The “semiconductor substrate 241” and the “semiconductor substrate 242” in an embodiment are examples of a “first substrate” and a “second substrate” in the present disclosure.

### Second Modification

In a second modification, another arrangement configuration of devices at the dielectric substrate 230 will be described.

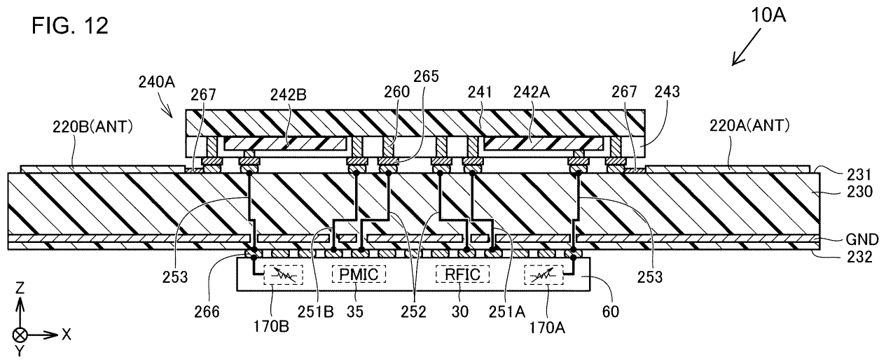

FIG. 12 is a perspective side view of a communication apparatus 10A according to the second modification. The communication apparatus 10A is configured such that radiating elements 220A and 220B are disposed on the main surface 231 of the dielectric substrate 230 and a SiP module 60A is disposed on the main surface 232 of the dielectric substrate 230.

In the communication apparatus 10A, the dimension in the X-axis direction of the dielectric substrate 230 is larger than that in the communication apparatus 10 described above with reference to FIG. 12. On the main surface 231, the radiating element 220A and the radiating element 220B are disposed in the X-axis positive direction and the X-axis negative direction with respect to an amplifier module 240A.

The amplifier module 240A includes circuits for the two radiating elements. Specifically, a semiconductor substrate 242A at which an amplifier for the radiating element 220A is formed and a semiconductor substrate 242B at which an amplifier for the radiating element 220B is formed are disposed on the semiconductor substrate 241. Furthermore, although not illustrated in FIG. 12, baluns and matching circuits for the individual radiating elements are disposed at the semiconductor substrate 241.

High frequency signals for the radiating elements 220A and 220B are supplied from the SiP module 60A disposed on the main surface 232 of the dielectric substrate 230, through power supply wires 251A and 251B, to the amplifier module 240A. Furthermore, the power supply voltages Vdd for the radiating elements 220A and 220B are supplied, through power supply wires 252, to the semiconductor substrates 242A and 242B.

In the communication apparatus 10A, an impedance adjustment circuit 170A for the radiating element 220A and an impedance adjustment circuit 170B for the radiating element 220B are arranged in the SiP module 60A. The impedance adjustment circuits 170A and 170B are electrically connected, through connecting wires 253, to the semiconductor substrates 242A and 242B, respectively. As in FIG. 11, the impedance adjustment circuits 170A and 170B may be arranged at the semiconductor substrate 241.

Also, with the configuration of FIG. 12, by forming an amplifier in which a relatively large current flows in the amplifier module 240A at the semiconductor substrate 242 made of a material for a low-loss group III-V compound and forming other circuits at the semiconductor substrate 241 made of an Si-based material or inside the SiP module 60A, an increase of the cost can be suppressed, and at the same time, circuit efficiency can be improved.

The “semiconductor substrate 242A” and the “semiconductor substrate 242B” in an embodiment are examples of a “second substrate” in the present disclosure.

The embodiments disclosed herein are to be considered in all respects to be illustrative and not restrictive. The scope of the present disclosure is defined by the claims, not by the description of the embodiments provided above, and is intended to include all modifications within the meaning and scope equivalent to the scope of the claims.

What is claimed is:

1. A transmission circuit comprising:
an input terminal;
an output terminal;
an amplifier circuit configured to amplify a high frequency signal received at the input terminal;
a first balun comprising an unbalanced line whose first end is connected to the output terminal, and a first balanced line and a second balanced line that are connected to the amplifier circuit, the first balun being configured to transmit the high frequency signal amplified by the amplifier circuit to the output terminal;
a power supply circuit configured to select, based on power of the high frequency signal, a discrete power supply voltage and to supply the selected power supply voltage to the amplifier circuit; and
an impedance adjustment circuit that is connected to a second end of the unbalanced line of the first balun, and that is configured to change a load impedance in accordance with the power supply voltage supplied to the amplifier circuit.

2. The transmission circuit according to claim 1, wherein the impedance adjustment circuit is configured to increase the load impedance as the power supply voltage supplied to the amplifier circuit decreases.

3. The transmission circuit according to claim 2,
wherein the power supply circuit is configured to transmit a control signal for changing the load impedance to the impedance adjustment circuit, and
wherein the power supply circuit is configured to switch, based on the selected power supply voltage, the control signal.

4. The transmission circuit according to claim 1, wherein the impedance adjustment circuit comprises a variable resistance circuit configured to adjust the load resistance.

5. The transmission circuit according to claim 4, wherein the variable resistance circuit comprises:
a plurality of resistors that are connected in parallel between the first balun and ground potential, and
switches that are connected in series with the individual resistors.

6. The transmission circuit according to claim 1, wherein the first balun is a Marchand balun.

7. The transmission circuit according to claim 1, further comprising:
a second balun comprising an unbalanced line whose first end is connected to the input terminal, and a first balanced line and a second balanced line that are connected to the amplifier circuit,
wherein the second balun is a Marchand balun.

8. The transmission circuit according to claim 7, wherein the amplifier circuit comprises:
a first amplifier configured to amplify a high frequency signal from the first balanced line of the second balun, and to supply the amplified high frequency signal to the first balanced line of the first balun, and
a second amplifier configured to amplify a high frequency signal from the second balanced line of the second balun, and to supply the amplified high frequency signal to the second balanced line of the first balun.

9. The transmission circuit according to claim 1,
wherein at least part of the transmission circuit is formed at a semiconductor substrate comprising a first substrate and a second substrate,
wherein the first substrate is a semiconductor substrate made of a material having an Si-based base material as a main component,
wherein the second substrate is a semiconductor substrate made of a material having a compound of an element from group III and an element from group V as a main component, and
wherein the amplifier circuit is formed at the second substrate.

10. The transmission circuit according to claim 9, wherein the impedance adjustment circuit is formed at the first substrate.

11. A communication apparatus comprising:
the transmission circuit according to claim 1;
a radiating element that is connected to the output terminal; and
a signal processing circuit configured to supply the high frequency signal to the transmission circuit.

12. The communication apparatus according to claim 11, further comprising:
a dielectric substrate that has a first surface and a second surface that are opposite to each other,
wherein the transmission circuit, the signal processing circuit, and the radiating element are on the first surface.

13. The communication apparatus according to claim 11, further comprising:
a dielectric substrate that has a first surface and a second surface that are opposite to each other,
wherein the amplifier circuit and the radiating element are on the first surface, and
wherein the signal processing circuit is on the second surface.

14. The communication apparatus according to claim 11, further comprising:
a system in package (SiP) module that comprises the signal processing circuit therein,
wherein the impedance adjustment circuit is inside the Sip module.
